(19) United States
(12) Patent Application Publication
(10) Pub. No.: US 2003/0027445 A1
(43) Pub. Date: Feb. 6, 2003

(54) Portective cove for pin interconnect

(76) Inventors: James M. Carney, Pepperell, MA (US); Robert S. Antonuccio, Burlington, MA (US); Timothy M. Holland, West Boylston, MA (US); Daniel D. Gonsalves, Hudson, MA (US); Paul V. Moruzzi, Upton, MA (US)

Correspondence Address: KUDIRKA & JOBSE, LLP, ONE STATE STREET, SUITE 1510, BOSTON, MA, 02109, US

(21) Appl. No.: 09/920,508

(22) Filed: Aug. 1, 2001

(51) Int. Cl. H05K 1/00; H01R 12/00

(52) U.S. Cl. 439/135; 439/76.1

(57) ABSTRACT

A protective cover for preventing damage and contamination to the pins within an electrical pin connector on a circuit board includes a semi-rigid housing defining an interior cavity. The housing is removably securable over the pin connector through an attachment mechanism which frictionally engages features on the pin connector and/or circuit board. In one embodiment, the housing includes one or more guide features to facilitate aligning the pin connector with the interior cavity of the housing. Multiple pin connectors may be accommodated within the interior cavity of the housing. Alternatively, the interior cavity may be partitioned into separate cavities, each of which may accommodate multiple pin connectors. A fin or rib may project from a surface of the housing to facilitate attachment or removal of the housing either manually or with a machine.

### FIELD OF THE INVENTION

The invention relates to electrical connectors, and more specifically, to a protective cover for preventing damage or contamination to electrical pin connectors on circuit boards.

### BACKGROUND OF THE INVENTION

Computers and other devices which include digital logic components typically embody one or more circuit boards populated with any of small, medium, or large scale logic components, typically in the form of integrated circuits, as well as occasional discreet components such as crystal oscillators, etc. Electrical signals and power are transferred between boards through pin connectors. As the sophistication of the integrated circuit components and the system architecture has increased, the density of the pin connectors has likewise increased. Many circuit boards in computers typically include multiple high-density pin connectors. These connectors enable circuit boards and other components to become physically and electronically coupled in a secure manner. Because the proper performance of the computer architecture relies on adequate electrical contact between the pin connectors and its receptacle, it is of critical importance that the integrity of the pins within a connector be protected from damage during the assembly, shipping and maintenance processes. Specifically, with large numbers of components being secured to a circuit board, many with automated robotic machines, there is a risk that damage may occur to a pin connector. Pins which are broken, bent, or mis-aligned, may not establish adequate electrical contact, causing system errors or even failure. Accordingly, a need exists for an apparatus to protect pin connectors, particularly high-density pin connectors from damage during the manufacturing and assembling processes in which the circuit boards are utilized.

The large number of pins associated with one or more connectors, which can typically range in the hundreds, requires substantial force to establish adequate coupling between the board containing the pin connector assembly and the board containing a complimentary mating socket. To reduce friction during the connection process, the pins within a connector are covered with a lubricant. Unfortunately, in the manufacturing environments, particularly in medium to high velocity airflow environments, dust, dirt, lint and other air borne impurities accumulate on the lubricated pins and may interfere with proper electrical contact once connected, or, if an air borne object is large enough, even cause damage to the pins. Accordingly, a need exists for a device which protects pin connectors, to which a lubricant has been applied, from airborne contaminants.

### SUMMARY OF THE INVENTION

A protective cover for preventing damage and contamination to electrical pin connector(s) on a circuit board includes a semi-rigid housing defining an interior cavity. The housing is removably securable over the pin connector(s) through an attachment mechanism which frictionally engages features on the pin connector and/or circuit board. In one embodiment, the housing includes one or more guide features to facilitate aligning the pin connector with the interior cavity of the housing. Multiple pin connectors may be accommodated within the interior cavity of the housing. Alternatively, the interior cavity may be partitioned into separate cavities, each of which may accommodate multiple pin connectors. A fin or rib may project from a surface of the housing to facilitate attachment or removal of the housing either manually or with a machine.

According to one aspect of the invention, an apparatus for protecting one or more pin connectors in a circuit board comprises a housing defining an interior cavity into which at least one pin connector is received and a mechanism for removably securing the housing over the pin connector. In one embodiment, the mechanism for removably securing the protective cover about the pin connectors comprises a plurality of irregularly shaped apertures which form an interfering fit with certain features present on the pin connectors or circuit board. In yet another embodiment, the interior cavity defined by the housing may be subdivided into a plurality of cavities, each of which may accommodate one or more pin connectors. In another embodiment, one or more projections may extend from the exterior surface of the housing to facilitate rapid installation or removal of the protective cover, as well as to guide the cover into alignment with the pin connector(s). The protective cover may have a unitary design which can be manufactured with an injection-molding process using a resin material.

According to another aspect of the invention, an apparatus for protecting one or more pin connectors in a circuit board comprises a housing defining an interior cavity into which at least one pin connector is received, a mechanism for removably securing the housing over the pin connector, and a mechanism for aligning the pin connector with the interior cavity.

According to another aspect of the invention, in a system having a circuit board and one or more electrical pin connectors affixed thereon, a method for preventing damage or contamination of the pin connector(s) comprises (a) providing a protective cover defining an interior cavity and having mechanisms for aligning the protective cover with features of the circuit board and for removably securing the protective cover over the pin connector(s); (b) aligning the protective cover with features of one of the printed circuit board and pin connector; and (c) removably securing the protective cover adjacent the circuit board so that the pin connector(s) are disposed within the interior cavity of the protective cover.

### BRIEF DESCRIPTION OF THE DRAWINGS

The above and further advantages of the invention may be better understood by referring to the following description in conjunction with the accompanying drawings in which:

FIG. 1 is a top view of the protective cover of the present invention;

FIG. 2 is an end view of the protective cover of FIG. 1;

FIG. 3 is a side, partially cut-away view of the protective cover of FIG. 1 as seen along line A-A of FIG. 1;

FIG. 4 is a bottom view of the protective cover of FIG. 1;

FIG. 5 is a top/side perspective view of the protective cover of FIG. 1;

FIG. 6 is a bottom/side perspective view of the protective cover of FIG. 1; and

FIG. 7 is an exploded perspective view illustrating two protective covers in relation to a circuit board and sets of pin connectors.

### DETAILED DESCRIPTION

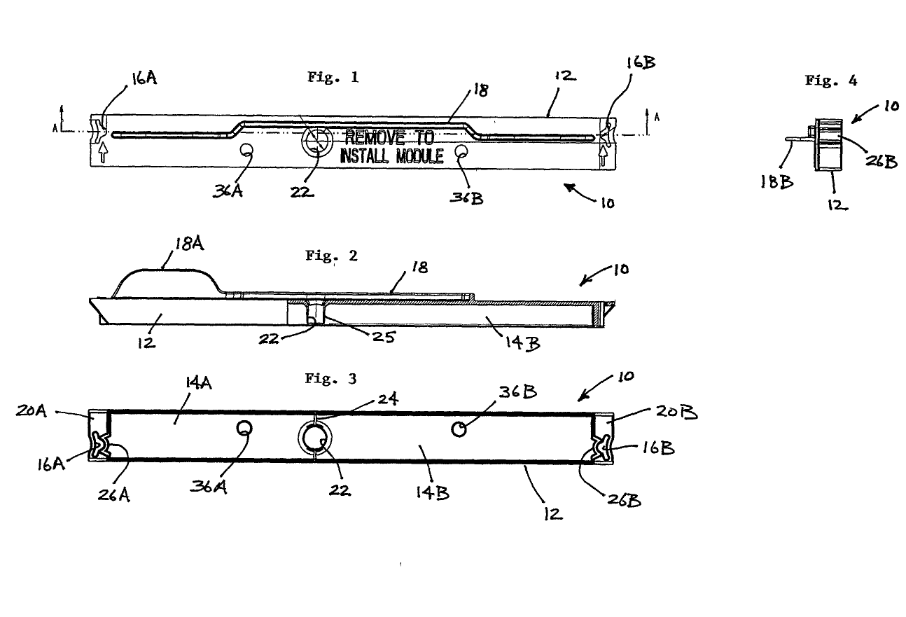

Referring to FIGS. 1-6, a protective cover 10 is shown in accordance with an illustrative embodiment of the invention. Protective cover 10 comprises a housing 12, an interior cavity 14, and alignment mechanisms 18, 26, 36 and securing mechanisms 16 integrally formed therein. In the illustrative embodiment, protective cover 10 may be of a unitary design and manufactured by an injection molding process. Materials suitable for use in manufacturing protective cover 10 include any rigid or semi-rigid material, such as natural or synthetic resin, including polyethylene and related families of plastics.

As illustrated, housing 12 of protective cover 10 has the shape of an elongate, rectangular five-sided box which defines interior cavity 14. One or more pin connectors may be disposed within interior cavity 14. The actual dimensions of housing 12 may be modified according to the size, shape and number of pin connectors to be covered and the mechanisms by which such pin connectors are attached to a circuit board. For example, any of the width, height, length, depth and configuration of the interior cavity of housing 12 may be left to the designer's discretion to accommodate the specific features for the pin connector(s) and the circuit board to which such pin connectors are attached. In the illustrative embodiment, protective cover 10 is designed for use with high-density pin connectors such as the VHDM product, commercially available from Teradyne, Inc., Hudson, N.H. Accordingly, the specific dimensions and shape of protective cover 10 to accommodate such pin connector(s) in the exemplary embodiment should not be considered limiting.

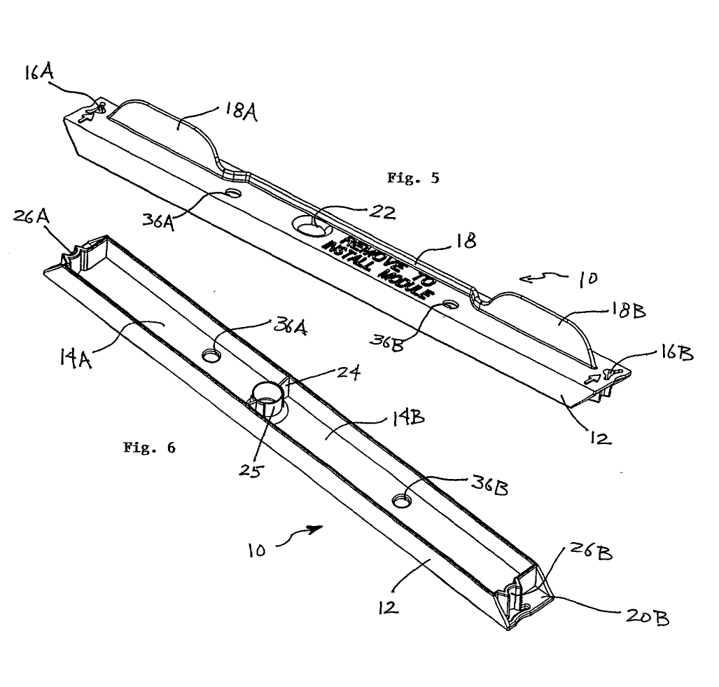

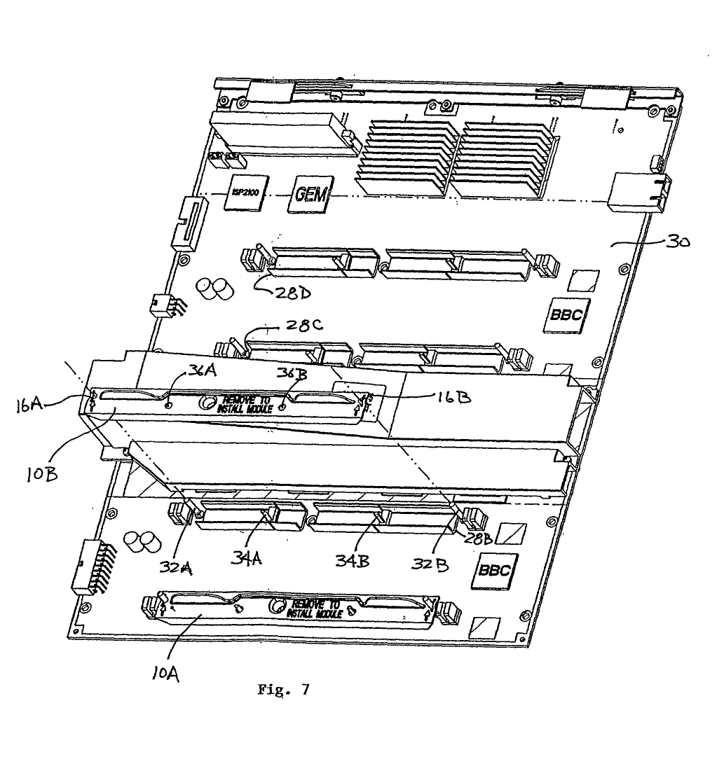

FIG. 7 illustrates two protective covers 10A-B in relation to a circuit board 30. As shown, circuit board 30 includes multiple sets of pin connectors 28A-D, each of which includes several connectors within the set and a set of primary posts 32A-B and secondary posts 34A-B. Each set of pin connectors 28A-D is separated by a threaded aperture for receiving a mounting screw (not shown). The mounting screw secures the circuit board 30 to its respective enclosure. As illustrated, such a screw may be extremely close to one or more pin connector which do not have end walls, thus the pins at this location are exposed and at risk to damage by the screw and the screw driver used. Protective cover 10 has a feature that helps guide the mounting screw that will not allow contact with the pin connectors to occur from the screw or screw driver, if accidentally installed at an angle. The feature, an aperture 22, as shown most clearly in FIGS. 3 and 5, extends from the top surface of housing 12 and into interior cavity 14 and is bordered by a cylindrical wall 25. Cylindrical wall 25 isolates aperture 22 from interior cavity 14. A wall 24 extends from cylindrical wall 25 to the inside surfaces of housing 12 thereby partitioning interior cavity 14 into a pair of cavities 14A-B.

Referring to FIGS. 3 and 6-7, the side surfaces of housing 12 include curved or arcuate shaped portions 26A-B which mimic the perimeter shape of primary cylindrical posts 32A-B, and, therefore, guide posts 32A-B during installation. A pair of secondary posts 34A-B are disposed intermediate the pin connectors, as illustrated. A pair of secondary apertures 36A-B extend through housing 12 and into interior cavities 14A-B, respectively to accommodate the secondary posts 34A-B, respectively. As such housing 12 provides integral guides to ensure proper installation of the protective cap 10.

The top surface of housing 12 extends beyond the housing side walls to form a pair of overhanging ridges 20A-B, one at each end of housing 12. One of a pair of apertures 16A-B extend through each of the overhanging ridges 20A-B, respectively, at the ends of protective cover 10 to form spring-like details. Apertures 16A-B each define an irregular shape which when mated with one of primary cylindrical posts 32A-B, respectively, produce an interfering fit, thereby frictionally securing the protective cover 10 over pin connector(s) 28. These spring-like details are designed for a friction fit, no hardware required. It will be obvious to those reasonably skilled in the arts that other mechanisms or means may be used to secure cover 10 to the pin connectors. Such mechanism may typically be dictated by the existing features of the pin connector and/or circuit board to which the protective cover 10 will be secured. For example, apertures 16A-B may be circular in shape to accommodate a threaded screw or other fastening device. In such embodiment, a nut may be threaded onto the threaded primary posts 32A-B or threaded secondary posts 34A-B once protective cover 10 is in place over the pin connector 28. In yet another embodiment, protective cover 10 may be manufactured with accurate tolerances so as to allow the walls of housing 12 to fit around the perimeter of pin connector 28 through only frictional engagement. Other fastening techniques may likewise be utilized.

As illustrated, a rib 18 extends from the top surface of housing 12 to facilitate rapid placement and removal of protective cover 10 as well as to facilitate ease of handling by an installer or assembler. In the illustrative embodiment rib 18 forms a pair of upwardly projecting tabs near each end of housing 12 to enable housing 12 to be easily grasped between the thumb and forefinger for placement or removal of the housing relative to the pin connectors. Rib 18 made also be sized and shaped to facilitate automated installation by machine.

An optional instructive legend and/or symbols may be displayed on the surface of housing 12. As shown in FIGS. 1 and 5, the legend “REMOVE TO INSTALL MODULE” is integrally formed in the top surface of housing 12, as well as a pair of arrows adjacent aperture 16A-B. Alternatively, such legend or symbols may be fixed to the surface of housing 12 with an adhesive label or may be printed thereon. Any message or instructions, or code may be displayed on the a surface of housing 12.

As illustrated in FIG. 7, circuit board 30 includes multiple sets of pin connectors 28A-D, each of which includes several pin connectors within the set. The bottom set of pin connectors 28A is shown covered by a protective cover 10A in accordance with the present invention. A second protective cover 10B is shown relative to pin connectors 28B with posts 32A-B aligned with apertures 16A-B, respectively, of protective cover 10B. To install, protective cover 10B is pressed down so that the primary posts 32A-B of pin connector set 28B are aligned with and engage the spring features of apertures 16A-B, respectively, while secondary posts 34A-B are aligned with secondary apertures 36A-B, respectively, and the protective cover 10B slips down around the pin connector 28B, protecting the pins from damage and air borne contaminants.

In the illustrative embodiment, protective cover 10 mechanically isolates the pin connector(s) 28, however, protective cover 10 does not provide an air-tight seal around the pin connector(s). In an alternative embodiment, depending on the surface features of the circuit board on which the cover will be secured, protective cover 10 may be manufactured with close tolerances to achieve or closely approximate an air-tight seal.

Having described herein illustrative embodiments of the present invention, persons of ordinary skill in the art will appreciate various other features and advantages of the invention apart from those specifically described above. It should therefore be understood that the foregoing is only illustrative of the principles of the invention, and that various modifications and additions can be made by those skilled in the art without departing from the spirit and scope of the invention. Accordingly, the appended claims shall not by the particular features which have been shown and described, but shall be construed also to cover any obvious modifications and equivalents thereof.

What is claimed is:

1. An apparatus for protecting one or more pin connectors on a circuit board comprising:
(a) a housing defining an interior cavity for receiving at least one pin connector; and
(b) a mechanism for removably securing the housing over the pin connector.

2. The apparatus of claim 1 wherein the interior cavity is partitioned into a plurality of cavities.

3. The apparatus of claim 1 wherein the plurality of cavities accommodate multiple pin connectors attached to the circuit board.

4. The apparatus of claim 1 wherein the mechanism for removably securing the housing over the pin connector comprises an aperture for engaging a structure on the circuit board.

5. The apparatus of claim 4 wherein the aperture has an irregular shape to create an interfering fit with the structure on the circuit board.

6. The apparatus of claim 1 further comprising a mechanism to enable removal of the housing from around the pin connector.

7. The apparatus of claim 6 wherein the mechanism to enable removal comprises a projection extending from a surface of the housing.

8. The apparatus of claim 7 wherein the mechanism to enable removal comprises a pair of projections extending from a surface of the housing.

9. The apparatus of claim 1 wherein the housing is formed of a semi-rigid material.

10. The apparatus of claim 9 wherein the housing is formed of a resin.

11. The apparatus of claim 10 wherein the housing is formed with an injection-molding process.

12. The apparatus of claim 1 further comprising:
an aperture extending through the housing and isolated from the interior cavity.

13. The apparatus of claim 4 wherein the mechanism for removably securing the housing to the pin connector comprises a plurality of apertures.

14. An apparatus for protecting one or more electrical pin connectors on a circuit board comprising:
(a) a housing defining an interior cavity for receiving at least one pin connector;
(b) a mechanism for removably securing the housing over the pin connector; and
(c) a mechanism for aligning the interior cavity of the housing with the pin connector.

15. The apparatus of claim 14 wherein the mechanism for aligning comprises at least one wall of the housing shaped to mimic a feature of one of the pin connector and circuit board.

16. The apparatus of claim 14 wherein the mechanism for aligning comprises at least one fin projecting from a surface of the housing to facilitate handling thereof.

17. The apparatus of claim 14 wherein the mechanism for aligning comprises at least one aperture shaped to accommodate a feature of one of the pin connector and circuit board.

18. In a computer system having a circuit board and one or more electrical pin connectors affixed thereon, a method for preventing damage or contamination of the pin connector comprising:
(a) providing a protective cover having an interior cavity defined therein and mechanisms for aligning the protective cover with features of the circuit board and for removably securing the protective cover over the pin connector;
(b) aligning the protective cover with features on one of the circuit board and pin connector; and
(c) removably securing the protective cover adjacent the circuit board so that the pin connector is disposed within the interior cavity of the protective cover.

19. The method of claim 18 wherein the features comprise a cylindrical projection and wherein the mechanism for aligning comprises an arcuate-shaped surface on the protective cover, and wherein (b) comprises:
(b.1) aligning the protective cover with the features so that the cylindrical projection is disposed along the arcuate surface of the protective cover.

20. The method of claim 18 wherein the features comprise a cylindrical projection and wherein the mechanism for removably securing comprises an irregular shaped aperture within the protective cover, and wherein (c) comprises:
(c.1) disposing the cylindrical projection within the irregular shaped aperture to frictionally secure the cylindrical projection therein when the pin connector is disposed within the cavity.
